(19) United States
(12) Patent Application Publication
(10) Pub. No.: US 2008/0069166 A1
(43) Pub. Date: Mar. 20, 2008

(54) Vertical-cavity surface-emitting laser

(75) Inventors: Eun-Hwa Lee, Suwon-si (KR); In Kim, Suwon-si (KR); Jun-Young Lee, Yongin-si (KR); Sung-Wook Kang, Seoul (KR); Do-Young Rhee, Yongin-si (KR)

Correspondence Address: CHA & REITER, LLC, 210 ROUTE 4 EAST STE 103, PARAMUS, NJ, 07652, US

(73) Assignee: Samsung Electronics Co.; LTD

(21) Appl. No.: 11/901,061

(22) Filed: Sep. 14, 2007

(30) Foreign Application Priority Data
Sep. 14, 2006 (KR) 2006-89190

(51) Int. Cl. H01S 5/026

(52) U.S. Cl. 372/50.11

(57) ABSTRACT

A vertical-cavity surface-emitting laser including an annular upper electrode disposed on a laser light exit surface, wherein an upper electrode aperture is formed therein and a light blocking layer is positioned at the center of the aperture formed in the upper electrode. The light blocking layer partially blocks laser light emitted from the vertical-cavity surface-emitting laser, providing a difference in reflectance in a transverse direction of the vertical-cavity surface-emitting laser, facilitating single mode oscillation.

### CLAIM OF PRIORITY

This application claims the benefit under 35 U.S.C. § 119(a) from a Korean Patent Application filed in the Korean Intellectual Property Office on Sep. 14, 2006 and assigned Serial No. 2006-89190, the contents of which are incorporated herein by reference in its entirety.

### BACKGROUND OF THE INVENTION

1. Field of the Invention

The present invention relates generally to a vertical-cavity surface-emitting laser. More particularly, the present invention relates to a vertical-cavity surface-emitting laser with an aperture.

2. Description of the Related Art

Conventional edge-emitting lasers, which emit light from surfaces, have a cavity structure parallel to a stacking direction of a plurality of layers constituting the laser devices. Such conventional edge-emitting lasers emit laser light in a direction parallel to the stacking direction.

Also known in the art are vertical-cavity surface-emitting lasers. Unlike edge-emitting lasers, vertical-cavity surface-emitting lasers have a cavity structure which is perpendicular to the stacking direction of a plurality of layers constituting the laser devices, and emit laser light in a direction perpendicular to the stacking direction.

Vertical-cavity surface-emitting lasers (VCSELs) feature a low driving current and a symmetric beam divergence. Moreover, a two-dimensional array of vertical-cavity surface-emitting lasers can be easily fabricated. A plurality of vertical-cavity surface-emitting lasers has been advantageously integrated into optoelectronic circuits together with passive optical waveguides on a single semiconductor wafer. Accordingly, VCSELs can be widely used in optical computers, optical communications, optical switching systems, etc.

In an effort to narrow a beam divergence angle of vertical-cavity surface-emitting lasers, changes to the size of an aperture, the size and position of an oxide layer, etc., have conventionally been proposed.

FIGS. 1 and 2 are sectional views illustrating conventional vertical-cavity surface-emitting lasers. Referring to FIGS. 1 and 2, respective conventional vertical-cavity surface-emitting lasers 100 and 200 include semiconductor substrates 101 and 201, lower reflective mirrors 110 and 210, oscillating regions 151 and 251, upper reflective mirrors 120 and 220, and contact layers 130 and 230. In addition, upper electrodes 103 and 203 are sequentially stacked on the semiconductor substrates 101 and 201, respectively. Lower electrodes 102 and 202 are disposed below the semiconductor substrates 101 and 201, respectively.

Still referring to FIGS. 1 and 2, respective current blocking layers 140 and 240, which are obtained by oxidizing doped impurities, are disposed on both sides of the top of the oscillating regions 151, 251. Each of the respective oscillating regions 151, 251 is formed between cladding layers for performing laser oscillation in the form of an active layer. Apertures 152, 252 are formed in central portions of the current blocking layers 140, 240 to allow passage of current and emission of oscillated laser light.

FIG. 1 illustrates the vertical-cavity surface-emitting laser 100 for improving a far-field pattern in which the width of an aperture 152 in the current blocking layer 140 is so narrow that only laser light oscillated in a fundamental mode is emitted.

FIG. 2 illustrates the vertical-cavity surface-emitting laser 200 in which the diameter of an aperture of the upper electrode 203 is so small that only laser light oscillated in higher-order modes is blocked.

In addition to the vertical-cavity surface-emitting lasers 100 and 200 respectively illustrated in FIGS. 1 and 2, vertical-cavity surface-emitting lasers can have a layered structure to improve far-field patterns have been proposed. In the proposed structure, a critical gain difference is caused by a difference in reflectance between the fundamental mode and any higher order mode by partial transverse surface etching of a contact layer, thereby resulting in an improvement in far-field patterns.

Referring back to FIG. 1, the vertical-cavity surface-emitting laser 100 can provide single-mode oscillation of laser light, but has a lower output power and a higher resistance than the VCSEL shown in FIG. 2.

Moreover, a process for manufacturing the vertical-cavity surface-emitting laser 100 has a narrow allowable tolerance range. That is, since the vertical-cavity surface-emitting laser 100 must be precisely manufactured, the likelihood of process defects increases due to the narrow tolerance range, thereby leading to secondary problems, such as yield reduction.

VCSELs such as the vertical-cavity surface-emitting laser 200 illustrated in FIG. 2, wherein an upper electrode has a narrow aperture, has a reduced quantity of laser light emitted due to the size of the narrow aperture. Thus, a higher critical current must be applied to obtain a desired output power, thereby resulting in a reduced efficiency and a higher critical current may increase the power consumed (and possibly wasted) in such devices to obtain the a higher critical current.

### SUMMARY OF THE INVENTION

An exemplary aspect of the present invention is to address at least some of the above problems and/or disadvantages known in the art, as well as to provide at least the advantages described below. Accordingly, one exemplary aspect of the present invention is to provide a vertical-cavity surface-emitting laser (VCSEL) capable of outputting laser light with a single-lobed (single mode) far-field pattern, while maintaining the size of an aperture formed in a current blocking layer or an upper electrode.

According to one possible construction of a first exemplary aspect of the present invention, there is provided a vertical-cavity surface-emitting laser including an annular upper electrode disposed on a laser light exit surface, which has an aperture formed therein; and a light blocking layer positioned at the center of the aperture formed in the upper electrode, which partially blocks laser light emitted from the vertical-cavity surface-emitting laser.

In some applications, the light blocking layer may cause a critical gain difference between the fundamental mode and any higher order mode of laser light by providing a difference in reflectance in the transverse direction of the vertical-cavity surface-emitting laser without requiring surface-etching to its structure. In addition, the light blocking layer can form a plurality of annular near-field patterns, thereby realizing single-mode far-field patterns which occur due to interference between the near-field patterns.

### BRIEF DESCRIPTION OF THE DRAWINGS

The above features and advantages of the present invention will become more apparent from the following detailed description when taken in conjunction with the accompanying drawings in which:

FIGS. 1 and 2 are sectional views illustrating conventional vertical-cavity surface-emitting lasers;

FIG. 3 is a sectional view illustrating a vertical-cavity surface-emitting laser according to a first exemplary embodiment of the present invention;

FIG. 4 is a plan view illustrating the vertical-cavity surface-emitting laser of FIG. 3, in which an upper electrode and a light blocking layer are disposed on a contact layer;

FIG. 5 is a sectional view illustrating a vertical-cavity surface-emitting laser according to a second exemplary embodiment of the present invention;

FIG. 6 is a sectional view illustrating a vertical-cavity surface-emitting laser according to a third exemplary embodiment of the present invention;

FIG. 7 is a plan view illustrating the vertical-cavity surface-emitting laser of FIG. 6;

FIG. 8 is a sectional view illustrating a contact layer of the vertical-cavity surface-emitting laser of FIG. 3;

FIGS. 9A through 10 are comparative graphs illustrating the exit patterns of a conventional vertical-cavity surface-emitting laser and a vertical-cavity surface-emitting laser according to an embodiment of the present invention;

FIG. 11 is a graph illustrating the reflectance of laser light for cases in which a light blocking layer is present and absent; and

FIGS. 12A and 12B are graphs illustrating light intensity with respect to a beam divergence angle in a vertical-cavity surface-emitting laser according to an embodiment of the present invention and a conventional vertical-cavity surface-emitting laser, respectively.

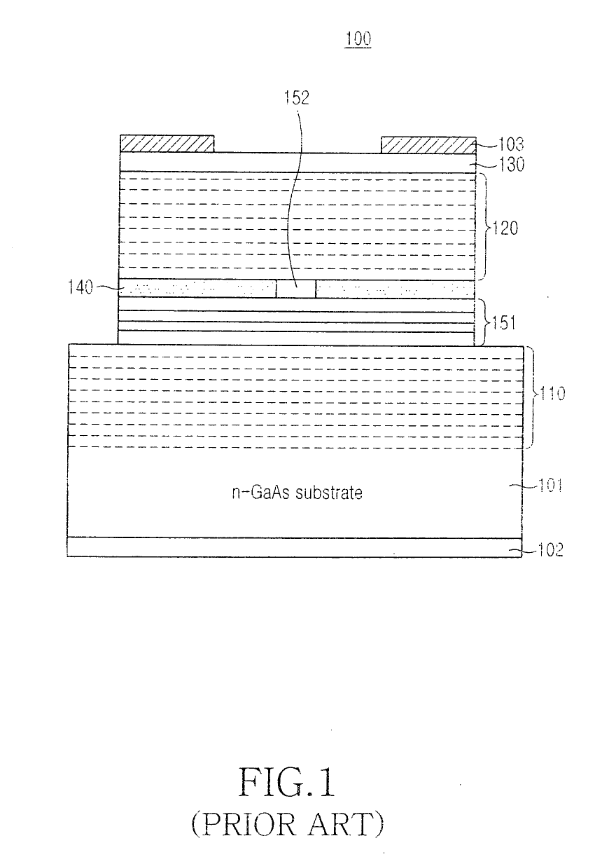

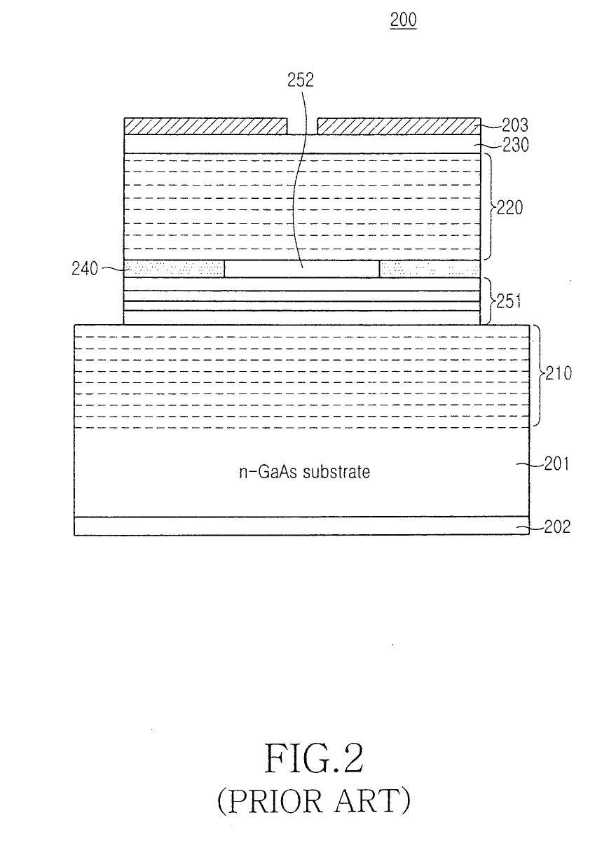

### DETAILED DESCRIPTION OF THE INVENTION

Several preferred exemplary embodiments of the present invention will now be described in detail with reference to the annexed drawings. The drawings have been provided for purposes of illustration and not to limit the invention to those examples shown. In the drawings, the same or similar elements are denoted by the same reference numerals even though they are depicted in different drawings. In the following description, a detailed description of known functions and configurations have been omitted for conciseness so as not to obscure appreciation of the present invention with unnecessary background information.

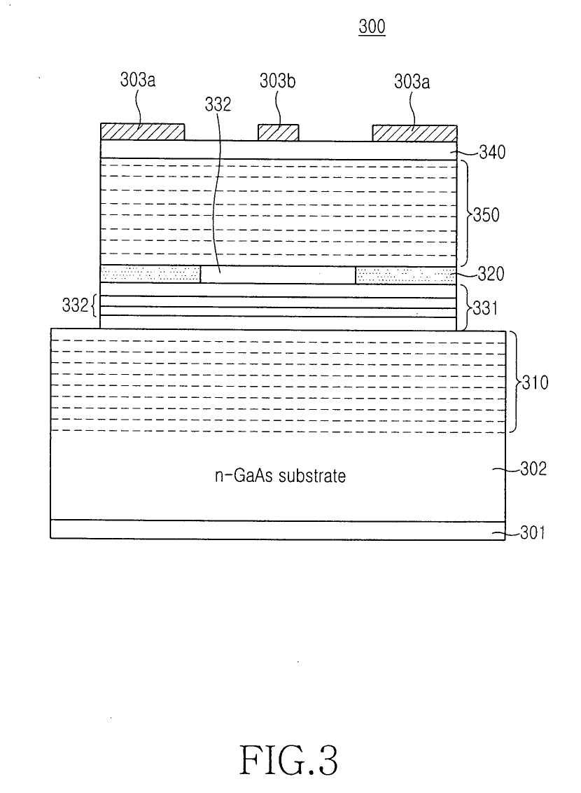

FIG. 3 is a sectional view illustrating a vertical-cavity surface-emitting laser 300 according to a first embodiment of the present invention. Referring to FIG. 3, the vertical-cavity surface-emitting laser 300 includes a semiconductor substrate 302, which may be formed of an n-GaAs substrate; a lower electrode 301 disposed below the semiconductor substrate 302; and a lower reflective mirror 310, a current blocking layer 320, an oscillating region 331, an upper reflective mirror 350, a contact layer 340, and an upper electrode 303a and a light blocking layer 303b which are sequentially stacked on the semiconductor substrate 302.

The current blocking layer 320 is disposed on both sides of the top of the oscillating region 331, and an aperture 332 allows for passage of current and emission of oscillated light formed in the current blocking layer 320. The oscillating region 331 includes an active layer 332 formed between cladding layers. The active layer has a multi-quantum-well structure capable of producing light. The produced light is resonated several times between the upper and lower reflective mirrors 350 and 310, and the resonated light is emitted as oscillated laser light.

The respective upper and lower reflective mirrors 350, 310 comprise a resonator for resonating light produced by the oscillating region 331. As an example, with respect to a vertical-cavity surface-emitting laser having an oscillation wavelength of 850 nm, the semiconductor substrate 302 may be an n-gallium arsenide (GaAs) substrate, and the lower reflective mirror 310 may be a stack of n-type aluminum gallium arsenide (AlGaAs) pairs, which have different compositions. In addition, the upper reflective mirror 350 may be comprised of a stack of p-type AlGaAs pairs, which have different compositions.

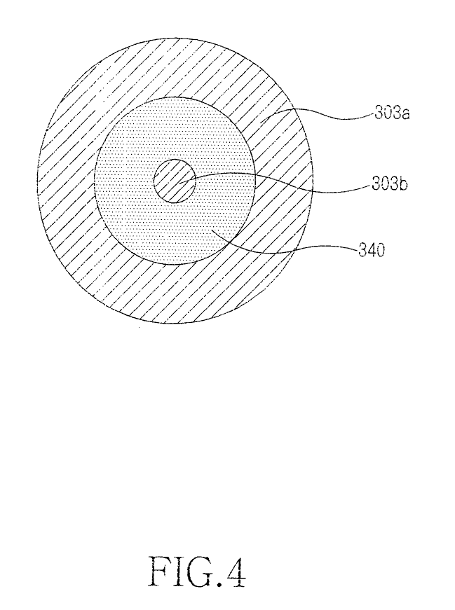

FIG. 4 is a plan view illustrating the vertical-cavity surface-emitting laser 300 of FIG. 3, wherein the upper electrode 303a and the light blocking layer 303b are disposed on the contact layer 340. Referring to FIG. 4, the upper electrode 303a is disposed on a laser light exit surface, and is arranged in the form of a ring with a centered aperture. The light blocking layer 303b positioned at the center of the aperture formed in the upper electrode 303a, which in this example is substantially annular in from as viewed from the top of the VCSEL 300, and serves to partially block laser light emitted from the VCSEL 300.

Still referring to FIGS. 3 and 4, the light blocking layer 303b may be formed of a material capable of reflecting laser light (e.g., metal), such as an electricity-flown material. The light blocking layer 303b may cause a critical gain difference between the fundamental mode and any higher order mode of oscillated laser light by causing a difference in reflectance in the transverse direction of the semiconductor substrate 302 without requiring surface-etching. The light blocking layer 303b may also form annular near-field patterns, thereby realizing single-mode far-field patterns which occur due to interference between the near-field patterns.

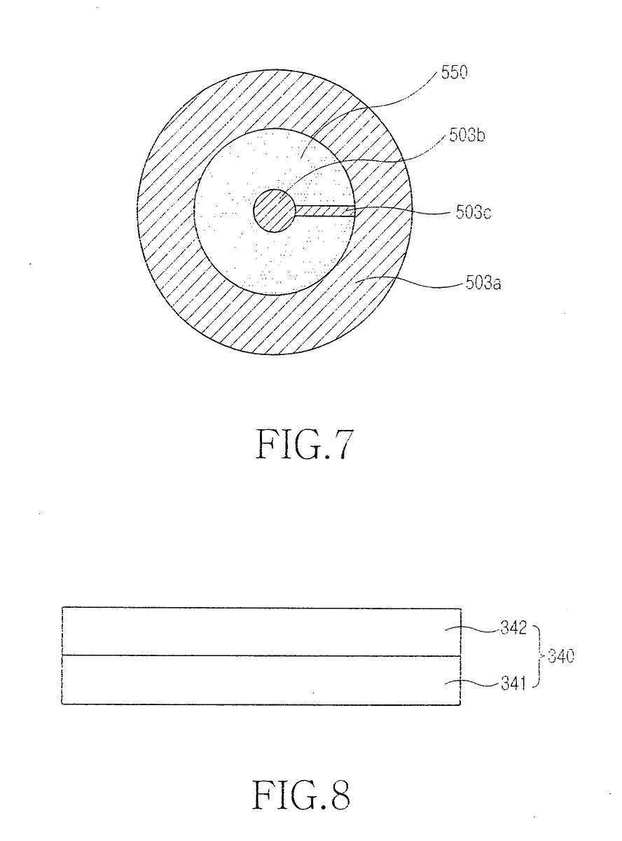

According to an exemplary aspect of the present invention, in order to compensate for a phase change of laser light caused by the highly reflective light blocking layer 303b positioned at the center of the light exit surface, the contact layer 340 may comprises a phase matching layer 341,342, as illustrated in FIG. 8. The light blocking layer 303b may be formed of a metal material, or the like.

Referring to FIG. 8 and FIG. 3, the contact layer 340 includes a first contact layer 341 and a second contact layer 342. The second contact layer 342 is stacked on the first contact layer 341 to a thickness sufficient to satisfy the Equation below with respect to the wavelength of oscillated laser light:

$$d = \frac{λ}{4 n} \qquad ( 1 )$$

where d is the physical thickness of the second contact layer 342, λ is the wavelength of laser light, and n is the refractive index of the second contact layer 342.

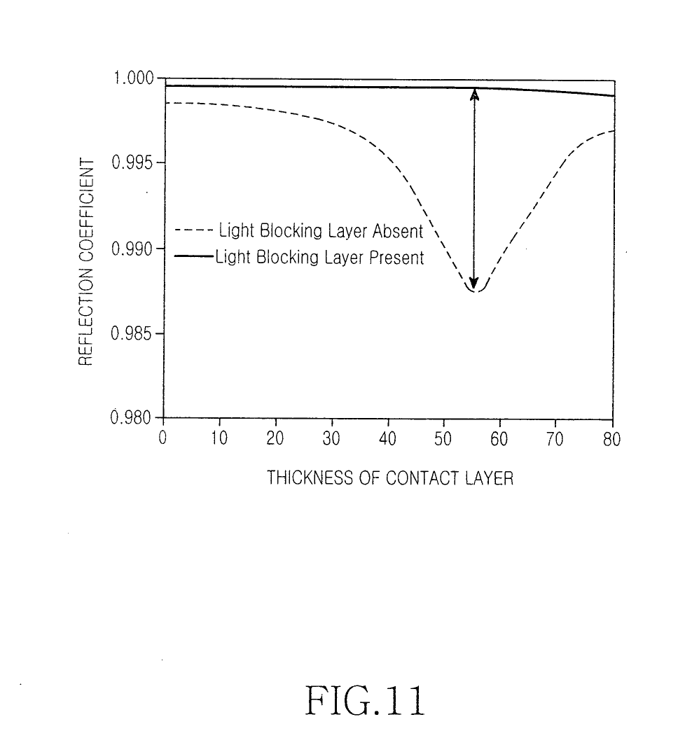

FIG. 11 is a graph illustrating the reflectance of laser light for cases in which a light blocking layer (such as 303b) is present and absent, and shows the reflectance result of laser light emitted from a vertical-cavity surface-emitting laser having a stack structure of 26 pairs for p-DBR and 35 pairs for n-DBR. In FIG. 11, a dotted line represents a change in reflectance with respect to the thickness of a portion of a contact layer on which no light blocking layer is disposed, and a solid line represents a change in reflectance with respect to the thickness of a portion of the contact layer on which a light blocking layer is disposed. Referring to FIG. 11, a reflectance pattern is changed with respect to the thickness of a contact layer.

Accordingly, based on the Equation (1) above, a difference in reflectance in the transverse direction of a substrate can be maximized by further forming a separate contact layer.

For example, with respect to a vertical-cavity surface-emitting laser having an oscillation wavelength of 850 nm, as illustrated in FIGS. 3 and 8, when the thickness of the second contact layer 342 is 55.8 nm, a difference in reflectance between the presence of light blocking layer 303b versus the absence of a light block layer (i.e. leaving an exposed surface of the contact layer 340) for emitting light is maximized. That is, when the thickness of the contact layer 340 is adjusted such that the reflectance of a center portion of the vertical-cavity surface-emitting laser 300 is greater than that of an edge portion of the vertical-cavity surface-emitting laser 300, the critical gains of higher order modes are increased, thereby ensuring a stable fundamental mode oscillation.

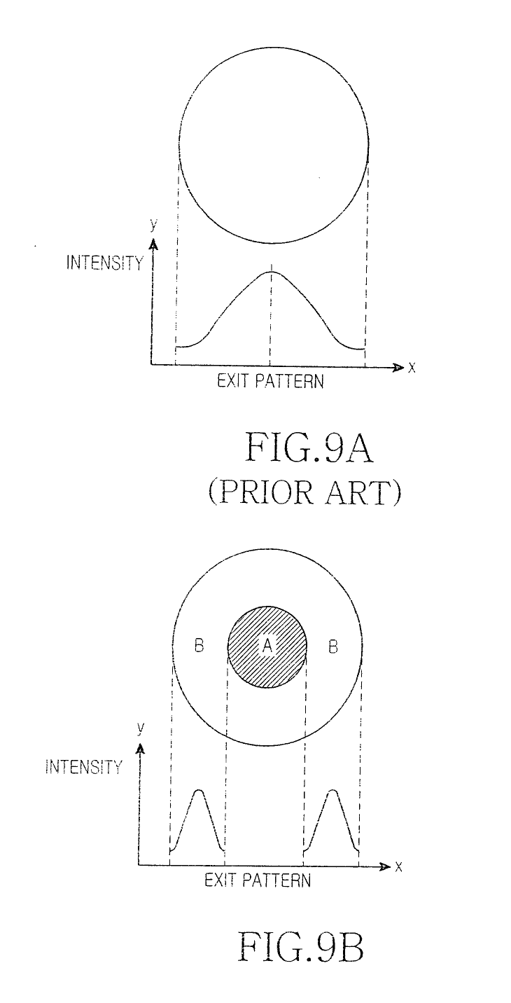

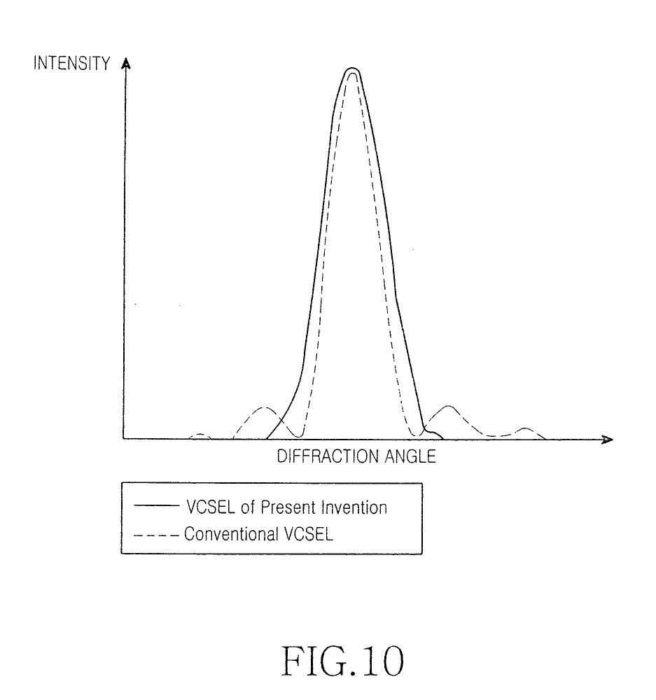

FIGS. 9A, 9B and 10 are comparative graphs illustrating exit patterns of a conventional vertical-cavity surface-emitting laser and a vertical-cavity surface-emitting laser according to an exemplary embodiment of the present invention. FIG. 9A graphically illustrates an intensity (y) of a laser exit pattern (x) at a light exit surface of a conventional vertical-cavity surface-emitting laser, and FIG. 9B graphically illustrates the intensity level (y) of a laser exit pattern at a light exit surface (x) of a vertical-cavity surface-emitting laser according to an exemplary embodiment of the present invention. FIG. 9B shows the intensity is blocked in the region A by the light blocking layer, as opposed to the intensity in the two areas “B” with the light blocking layer region A in between.

Therefore, according to an exemplary aspect of the present invention, laser light emitted from a vertical-cavity surface-emitting laser is blocked by a light blocking layer, and thus, forms annular near-field patterns immediately after the emission. Thus, the far-field patterns of the laser light have side-lobes (shown in FIG. 9B) with a low intensity due to an interference phenomenon but have a narrower center portion than those of conventional laser light, as illustrated in FIG. 10. In FIG. 10, a solid line represents an exit pattern of laser light emitted from a conventional vertical-cavity surface-emitting laser, and a dotted line represents an exit pattern of laser light emitted from a vertical-cavity surface-emitting laser according to an embodiment of the present invention.

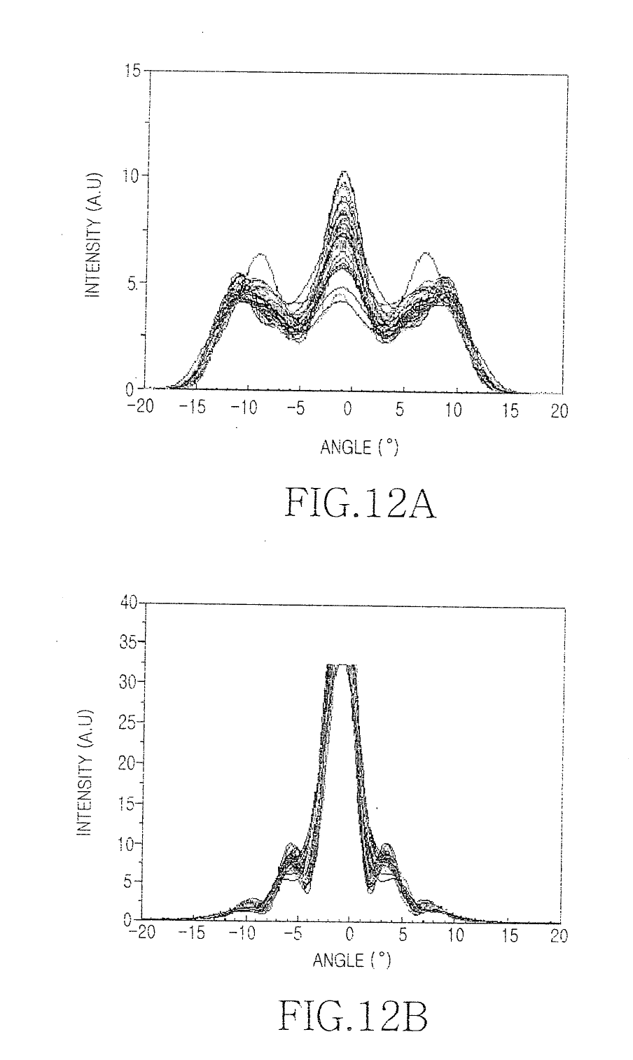

FIGS. 12A and 12B illustrate experimental results for 40 continuous laser light beams with an output power of 1 mW when an aperture of an oxide layer is 16 μm in diameter. FIG. 12A illustrates experimental results for a vertical-cavity surface-emitting laser including a further stacked contact layer and a light blocking layer according to the present invention, and FIG. 12B illustrates experimental results for a vertical-cavity surface-emitting laser with no further stacked contact layer and light blocking layer.

Referring to FIG. 12A, the vertical-cavity surface-emitting laser including the light blocking layer shows single mode-like far-field patterns even though the diameter of the aperture of the oxide layer is too large to form a single lobe. Moreover, the 40 continuous laser beams show good light uniformity.

Referring to FIG. 12B, some of the maximum intensities do not appear since a detector used in the experiments was saturated near the divergence angle of 0 degrees. Of course, however, the overall characteristics can be easily understood by those of ordinary skill in the art.

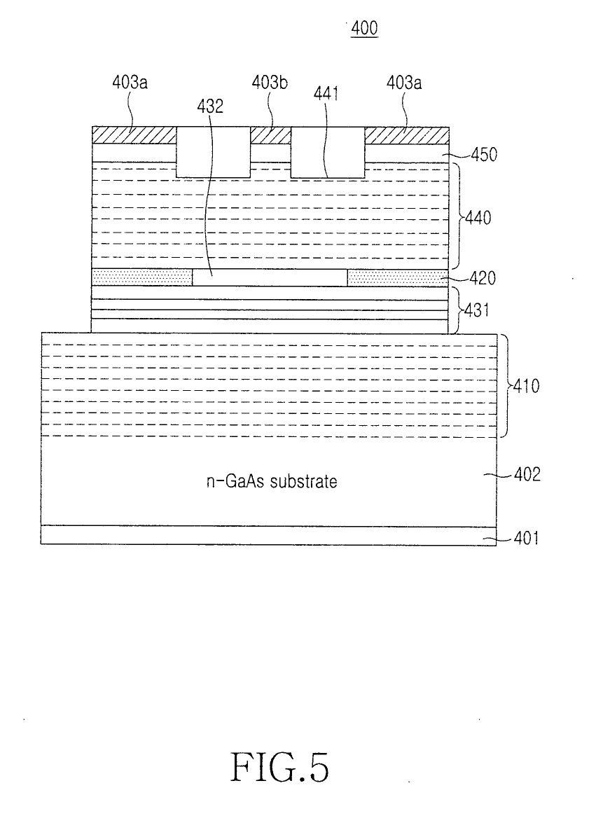

FIG. 5 is a sectional view illustrating a vertical-cavity surface-emitting laser 400 according to a second exemplary embodiment of the present invention. Referring to FIG. 5, the vertical-cavity surface-emitting laser 400 includes a semiconductor substrate 402; a lower electrode 401 disposed below the semiconductor substrate 402; a lower reflective mirror 410, an oscillating region 431, an upper reflective mirror 440, a contact layer 450, and an upper electrode 403a and a light blocking layer 403b, which are sequentially stacked on the semiconductor substrate 402; and a current blocking layer 420. An aperture 432 allows for passage of an oscillated laser light and current is formed on the top portion of the oscillating region 431 in which there is not disposed the current blocking layer 420.

In the vertical-cavity surface-emitting laser 400 of the second exemplary embodiment of the present invention, in order to make light reflectance at the light exit portion smaller than that at the center portion, a groove 441 is formed between the light blocking layer 403b and the upper electrode 403a. The groove 441 extends from the contact layer 450 to a portion of the upper reflective mirror 440. The groove 441 has a lower number of DBR pairs constituting a reflective mirror than the other portions, and thus, provides a lower reflectance. As a result, a critical gain value of higher order mode oscillation is increased, thereby preventing oscillation.

With regard to the second exemplary embodiment shown in FIG. 5, the other constitutions and structures are similar with respect to the first exemplary embodiment of the present invention as described above, and thus, a description about the same components as those in the first exemplary embodiment of the present invention will not be given.

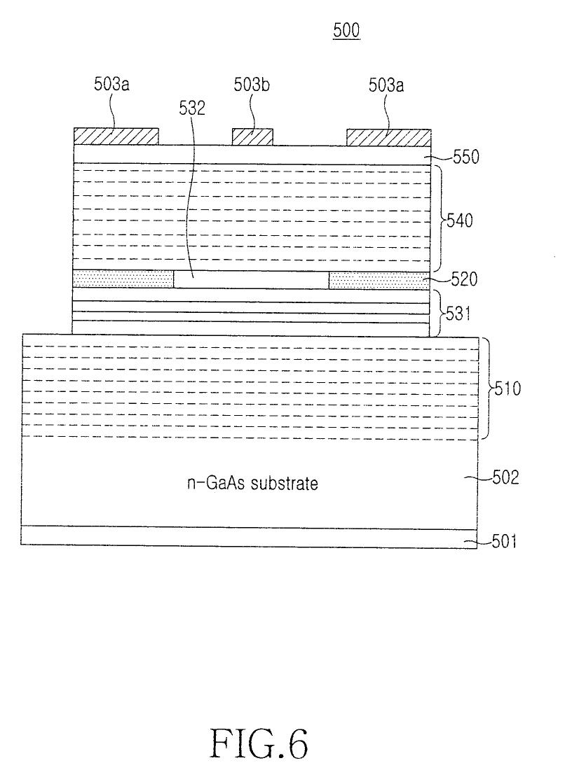

FIG. 6 is a sectional view illustrating a vertical-cavity surface-emitting laser 500 according to a third exemplary embodiment of the present invention. Referring to FIG. 6, the vertical-cavity surface-emitting laser 500 includes a semiconductor substrate 502; a lower electrode 501 disposed below the semiconductor substrate 502; a lower reflective mirror 510, an oscillating region 531, an upper reflective mirror 540, a contact layer 550, and an upper electrode 503a and a light blocking layer 503b, which are sequentially stacked on the semiconductor substrate 502; and a current blocking layer 520. A description about the same or similar constitutions and related operations as those in the first exemplary embodiment of the present invention will not be given below. An aperture 532 allows for passage of current and an oscillated light is formed in the current blocking layer 520 on the oscillating region 531.

FIG. 7 is a plan view illustrating the vertical-cavity surface-emitting laser (500) of FIG. 6. Referring to FIG. 7, the light blocking layer 503b is electrically connected to the upper electrode 503a. When the light blocking layer 503b is electrically connected to the upper electrode 503a via the portion 503c, like in the present exemplary embodiment, a current distribution is made uniform, thereby facilitating a fundamental mode oscillation of laser light.

According to the present invention, a circular light blocking layer is positioned at the center of an annular upper electrode. Thus, laser light with single-lobed far-field patterns having a fundamental mode can be produced from near-field patterns. That is, since it is not necessary to adjust the size of an aperture formed in a current blocking layer or an upper electrode, so that a vertical-cavity surface-emitting laser can be manufactured within an allowable process tolerance range, and an increase in critical current due to size reduction of an aperture formed in an upper electrode can be prevented.

While the present invention has been particularly shown and described with reference to particular exemplary embodiments thereof, those skilled in the art will appreciate that the disclosed preferred embodiments of the invention are used in a generic and descriptive sense only and not for purposes of limitation, and that various changes may be made and equivalents substituted for elements thereof without departing from the spirit of the invention and the scope of the appended claims as set forth herein below. For example, while the upper electrode shown in the examples is annularly shaped, it within the spirit of the invention to use another geometric shape.

What is claimed is:

1. A vertical-cavity surface-emitting laser comprising:
an upper electrode disposed on a laser light exit surface and having an aperture formed in a central portion thereof; and
a light blocking layer positioned at the central portion of the aperture formed in the upper electrode, wherein the light blocking layer partially blocks laser light emitted from the vertical-cavity surface-emitting laser

2. The vertical-cavity surface-emitting laser of claim 1, wherein the upper electrode comprises an annular electrode.

3. The vertical-cavity surface-emitting laser of claim 1, further comprising:
a semiconductor substrate;
a lower reflective mirror stacked on the semiconductor substrate;
an oscillating region stacked on the lower reflective mirror; and
an upper reflective mirror and a contact layer sequentially stacked on the oscillating region,
wherein the upper electrode and the light blocking layer are disposed on the contact layer.

4. The vertical-cavity surface-emitting laser of claim 3, wherein the light blocking layer is formed of a metal material.

5. The vertical-cavity surface-emitting laser of claim 1, wherein the light blocking layer is formed of an electricity-flown material.

6. The vertical-cavity surface-emitting laser of claim 1, wherein the light blocking layer and the upper electrode are electrically connected to each other.

7. The vertical-cavity surface-emitting laser of claim 3, wherein a groove is formed between the light blocking layer and the upper electrode and extends to a portion of the upper reflective mirror from the contact layer.

8. The vertical-cavity surface-emitting laser of claim 7, wherein the groove 441 has a lower number of DBR pairs constituting a reflective mirror than the other portions, and thus, provides a lower reflectance

9. The vertical-cavity surface-emitting laser of claim 3, further comprising a current blocking layer disposed on both sides of the top of the oscillating region.

10. The vertical-cavity surface-emitting laser of claim 1, wherein upper electrode layer and the light blocking layer are electrically connected.

11. The vertical-cavity surface-emitting laser of claim 1, wherein the upper electrode layer and the light blocking layer are made of the same material.

12. The vertical-cavity surface-emitting laser of claim 3, wherein the semiconductor substrate layer comprises an n-GaAs substrate.

13. The vertical-cavity surface-emitting laser of claim 1, wherein the light blocking layer is formed of a material capable of reflecting laser light.

14. The vertical-cavity surface-emitting laser of claim 1, wherein the blocking layer is arranged to provide a critical gain difference between a fundamental mode and any higher order mode of oscillated laser light by causing a difference in reflectance in the transverse direction of the semiconductor substrate without requiring surface-etching.

15. The vertical-cavity surface-emitting laser of claim 3, wherein the contact layer comprises:
a first contact layer stacked on the upper reflective mirror; and
a second contact layer disposed on the first contact layer, wherein the second contact layer satisfies the Equation below with respect to the wavelength of oscillated laser light:
$$d = \frac{λ}{4 n}$$
where d is a physical thickness of the second contact layer, λ is the wavelength of the laser light, and n is the refractive index of the second contact layer.

16. The vertical-cavity surface-emitting laser of claim 3, wherein the contact layer comprises a phase matching layer
